(19) United States
(12) Patent Application Publication
(10) Pub. No.: US 2025/0199718 A1
(43) Pub. Date: Jun. 19, 2025

(54) MEMORY CONTROLLER AND MEMORY SYSTEM INCLUDING THE SAME

(71) Applicant: SK hynix Inc., Gyeonggi-do (KR)

(72) Inventor: Choung Ki SONG, Gyeonggi-do (KR)

(21) Appl. No.: 18/585,982

(22) Filed: Feb. 23, 2024

(30) Foreign Application Priority Data
Dec. 19, 2023 (KR) 10-2023-0185698

(51) Int. Cl. G06F 3/06

(52) U.S. Cl. CPC G06F 3/0658; G06F 3/0619; G06F 3/0688

(57) ABSTRACT

A memory system includes a plurality of memory modules; a plurality of module controllers configured to respectively control the plurality of memory modules; and a plurality of interface circuits configured to interface the plurality of memory modules with the plurality of module controllers, wherein, according to a setting signal, at least one target interface circuit is configured to interface a target module controller among the plurality of module controllers with a target memory module among the plurality of modules, or interfaces other module controllers different from the target module controller with the target memory module.

### CROSS-REFERENCE TO RELATED APPLICATION

The present application claims the benefit of Korean Patent Application No. 10-2023-0185698, filed on Dec. 19, 2023, which is incorporated herein by reference in its entirety.

### BACKGROUND

### 1. Field

Various embodiments of the present disclosure relate to a semiconductor design technology, and more particularly, to a memory system including a memory controller for performing an error correction operation.

### 2. Description of the Related Art

A memory system may store data provided from an external device and provide the stored data to the external device. The memory system may include an error correction circuit to ensure the reliability of data. Recently, a memory device may store data and an error correction code together, and the error correction circuit may perform an error correction operation of detecting and correcting an error of data read from the memory device using an error correction code read from the memory device.

### SUMMARY

Embodiments of the present disclosure are directed to a memory controller capable of flexibly adjusting the error correction capability according to settings, and a memory system including the same.

According to an embodiment of the present disclosure, a memory system includes a plurality of memory modules; a plurality of module controllers configured to respectively control the plurality of memory modules; and a plurality of interface circuits configured to interface the plurality of memory modules with the plurality of module controllers, wherein, according to a setting signal, at least one target interface circuit is configured to interface a target module controller among the plurality of module controllers with a target memory module among the plurality of modules, or interfaces other module controllers different from the target module controller with the target memory module.

According to an embodiment of the present disclosure, a memory system includes first to third memory modules; first to third module controllers configured to generate user data and an error correction code for the first to third memory modules, respectively; and first to third interface circuits configured to transmit/receive the user data and the error correction code to/from the first to third memory modules, respectively, through independent channels, wherein the first and second module controllers are configured to respectively increase a size of the error correction code according to a setting signal to generate first and second extended error correction codes, and wherein the third interface circuit is configured to transmit and receive the first and second extended error correction codes to and from the third memory module according to the setting signal. According to an embodiment of the present disclosure, a memory controller includes first to third module controllers configured to generate user data and an error correction code for first to third memory modules, respectively; and first to third interface circuits configured to transmit and receive the user data and the error correction code to and from the first to third memory modules, respectively, through independent channels, wherein the first and second module controllers are configured to respectively increase a size of the error correction code according to a setting signal to generate first and second extended error correction codes, and wherein the third interface circuit is configured to transmit and receive the first and second extended error correction codes to and from the third memory module according to the setting signal.

Further, according to embodiments of the present disclosure, the memory system may increase the error correction capability only in an extended mode in which the error correction capability with the high performance is required, thereby flexibly performing the error correction operation depending on the system environment.

### BRIEF DESCRIPTION OF THE DRAWINGS

FIG. 1 is a block diagram illustrating a data processing system according to an embodiment of the present disclosure.

FIG. 2 is a block diagram illustrating a memory system according to a first embodiment of the present disclosure.

FIG. 3 is a circuit diagram illustrating a first physical circuit of FIG. 2, according to an embodiment of the present disclosure.

FIG. 4 is a block diagram illustrating a memory system according to a second embodiment of the present disclosure.

FIG. 5 is a diagram for describing a connection between a third physical interface circuit and a third memory module of FIG. 4, according to an embodiment of the present disclosure.

FIG. 6 is a diagram for describing input/output signals between a module control logic and a memory interface logic of FIG. 4, according to an embodiment of the present disclosure.

FIGS. 7A and 7B are circuit diagrams of the third physical interface circuit of FIG. 6, according to an embodiment of the present disclosure.

FIGS. 8A and 8B are diagrams for describing a configuration of a memory system according to a setting signal according to an embodiment of the present disclosure.

FIG. 9 is a diagram for describing a modified example of a memory system according to an embodiment of the present disclosure.

FIG. 10 is a diagram for describing another modified example of a memory system according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

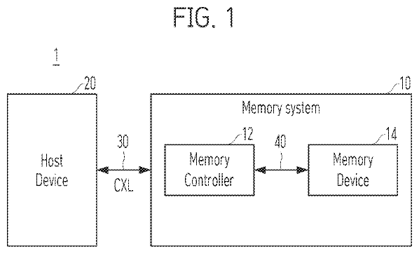

FIG. 1 is a block diagram illustrating a data processing system 1 according to an embodiment of the present disclosure.

Referring to FIG. 1, the data processing system 1 may include

a host device 20 and a memory system 10.

The memory system 10 may include a memory controller 12 and a memory device 14. The memory system 10 may store data under the control of the host device 20, such as a cellular phone, a smartphone, an MP3 player, a laptop computer, a desktop computer, a game player, a TV, a tablet PC, or an in-vehicle infotainment system. The host device 20 may be an external device of the memory system 10.

The memory system 10 may be manufactured as any of various types of memory modules depending on a host interface that is a communication method with the host device 20. The memory system 10 may be configured with any of various types of memory modules, such as an SSD, a multimedia card in a form of an MMC, an eMMC, an RS-MMC, and a micro-MMC, a secure digital card in a form of an SD, a mini-SD, and a micro-SD, a universal serial bus (USB) memory module, a universal flash storage (UFS) device, a personal computer memory card international association (PCMCIA) card type memory module, a peripheral component interconnection (PCI) card type memory module, a PCI express (PCI-E) card type memory module, a compact flash (CF) card, a smart media card, and a memory stick.

The memory system 10 may be manufactured in any of various package types. For example, the memory system 10 may be manufactured in any of various package types such as a package on package (POP), a system in package (SIP), a system on chip (SOC), a multi-chip package (MCP), a chip on board (COB), a wafer-level fabricated package (WFP), a wafer-level stack package (WSP), etc.

The memory device 14 may store data. The memory device 14 operates under control of the memory controller 12. The memory device 14 may include a memory cell array including a plurality of memory cells that store data. In an embodiment, the memory cell array may include a plurality of memory blocks. Each memory block may include a plurality of memory cells. The memory block may be a unit for an erase operation. One memory block may include a plurality of pages. In an embodiment, the page may be a unit for storing data in the memory device 14 or reading data stored in the memory device 14.

In an embodiment, the memory device 14 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory, a resistive random access memory (RRAM), a phase-change random access memory (PRAM), a magnetoresistive RAM (MRAM), a ferroelectric RAM (FRAM), a spin transfer torque RAM (STT-RAM), or others.

The memory device 14 may receive a command and an address from the memory controller 12 and access an area selected by the address of the memory cell array. That is, the memory device 14 may perform an operation instructed by the command on the area selected by the address. For example, the memory device 14 may perform a write operation (e.g., a program operation) to write data to the area selected by the address. During a read operation, the memory device 14 may read data from the area selected by the address.

The memory controller 12 may control an overall operation of the memory system 10. The memory controller 12 may control the memory device 14 to perform the write operation, the read operation, or other operations according to a request from the host device 20. For example, during the write operation, the memory controller 12 may provide a write command, an address, and data to the memory device 14. During the read operation, the memory controller 12 may provide a read command and an address to the memory device 14.

The host device 20 may communicate with the memory system 10 using a communication method or standard such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a compute express link (CXL), a universal flash storage (UFS), a secure digital (SD), a multi-media card (MMC), an embedded MMC (eMMC), a dual in-line memory module (DIMM), a registered DIMM (RDIMM), and a load reduced DIMM (LRDIMM).

In an embodiment, the host device 20 may communicate with the memory system 10 through a first interface 30. The first interface may be referred to as a host interface. The first interface 30 may include an interface implemented based on a compute express link (CXL) protocol. The CXL protocol may use a serial interface. The CXL interface is an interface based on a PCIe, and may be an interface designed for a Central Processing Unit (CPU), a Graphic Processing Unit (GPU), and various types of accelerators to use memory more efficiently. By connecting the memory system 10 to the host device through the CXL interface, the memory capacity of a computer system such as a data center and a server can be increased, and various processors in the computer system can share the memory device.

The memory controller 12 and the memory device 14 may communicate through a second interface 40. The second interface 40 may be referred to as a memory interface. The second interface 40 may include an interface implemented based on a dual inline memory module (DIMM) protocol.

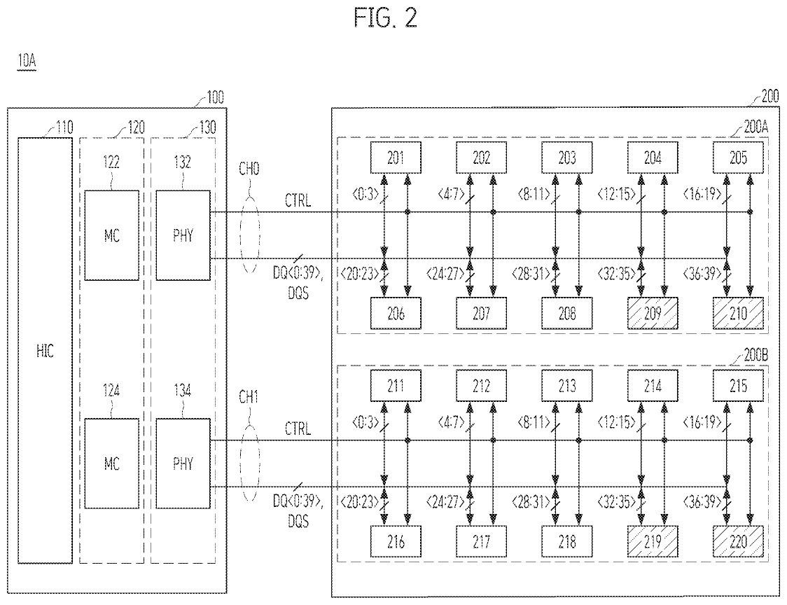

FIG. 2 is a block diagram illustrating a memory system 10A according to a first embodiment of the present disclosure.

Referring to FIG. 2, the memory system 10A may include a memory controller 100 and a memory device 200.

The memory controller 100 may include a host interface circuit (HIC) 110, a module control logic 120, and a memory interface logic 130.

The host interface circuit 110 may communicate with the host device (20 in FIG. 1) through a host interface. The host interface circuit 110 may communicate with a host through a CXL interface.

The module control logic 120 may be coupled to the memory device 200 through the memory interface logic 130 and control the overall operation of the memory device 200.

The memory interface logic 130 may communicate with the memory device 200 through a memory interface. The memory interface logic 130 may transmit control signals including a chip selection signal and a command/address signal to the memory device 200 through control signal lines CTRL, and transmit/receive data and a strobe signal to/from the memory device 200 through data lines DQ<0:39> and a strobe line DQS, respectively. According to an embodiment, the memory interface logic 130 may transmit a clock signal to the memory device 200 through a separate clock line (not shown). The memory interface logic 130 may communicate with the memory device 200 through a DIMM interface.

The memory device 200 may include a plurality of memory modules that independently communicate with the memory controller 100 through channels CH0 and CH1 that are separated from each other. When the memory device 200 is composed of a plurality of memory modules, the memory interface logic 130 may be composed of a plurality of physical interface circuits PHYs respectively corresponding to the plurality of memory modules, to communicate with a corresponding memory module through a dedicated channel. In addition, the module control logic 120 may also be composed of a plurality of module controllers MCs respectively corresponding to the plurality of physical interface circuits PHYs to control a corresponding memory module.

For example, as illustrated in FIG. 2, the memory device 200 may include first and second memory modules 200A and 200B, and each of the first and second memory modules 200A and 200B may include 10 memory packages. The module control logic 120 may include first and second module controllers 122 and 124 for controlling the first and second memory modules 200A and 200B, respectively. The memory interface logic 130 may include first and second physical interface circuits 132 and 134 communicating with the first and second memory modules 200A and 200B through first and second channels CH0 and CH1, respectively.

The first physical interface circuit 132 may be coupled to the 10 memory packages 201 to 210 through the first channel CH0. The first physical interface circuit 132 may transmit/receive data to/from the 10 memory packages 201 to 210 through the 40 data lines DQ<0:39>. For example, the memory package 201 may input and output data through the four data lines DQ<0:3>, and the memory package 202 may input and output data through the four data lines DQ<4:7>. In this case, the number of bits of data input and output at a time may be determined according to a burst length. For example, when the burst length is set to 16, each of the memory packages 201 to 210 may input and output 8 bytes (i.e., 4*16 bits) of data at a time.

The first physical interface circuit 132 may transmit/receive a strobe signal to/from the 10 memory packages 201 to 210 through the strobe line DQS. The strobe signal may be transmitted together with the data to synchronize an input and an output of data. According to an embodiment, when the strobe signal is differentially input, two strobe lines DQS may be arranged.

In addition, the first physical interface circuit 132 may transmit control signals including a chip selection signal and a command/address signal to the memory packages 201 to 210 through the control signal lines CTRL. The control signal lines CTRL may be coupled in common to the memory packages 201 to 210 and shared between the memory packages 201 to 210. The first physical interface circuit 132 may transmit a clock signal to the memory device 200 through a separate clock line (not shown).

Each of the memory packages 201 to 220 may include one or more memory chips (e.g., DRAM chips). A plurality of memory chips included in the memory package may be stacked using 3DS (3-dimensional stacking) or wire bonding. However, the embodiments of the present disclosure are not limited thereto, and each of the memory packages 201 to 220 may include different types of memory chips. For example, at least one of the memory packages 201 to 220 may have a configuration different from that of the other memory packages, and/or may be coupled to the memory controller 100 by using different methods. The form factor of the memory module may have various forms such as an Add-in-Card (AIC) and an Enterprise and Data Center SSD Form Factor (EDSFF).

Some (e.g., 8) memory packages 201 to 208 among the 10 memory packages 201 to 210 may be used to store user data, and the remaining two memory packages 209 and 210 (e.g., two) may be used to store an error correction code. Accordingly, 32-bit user data and an 8-bit error correction code per a burst length may be input/output to/from one memory module. For example, when the burst length is set to 16, the memory packages 201 to 208 may input/output 64-byte user data at a time, and the memory packages 209 and 210 may input/output a 16-byte error correction code at a time.

The second physical interface circuit 134 may be coupled to 10 memory packages 211 to 220 through the second channel CH1. The second physical interface circuit 134 may have substantially the same configuration as the first physical interface circuit 132.

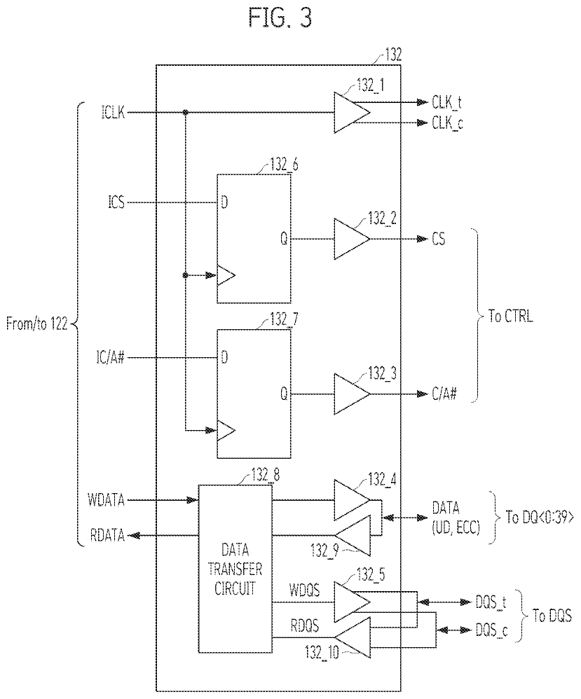

FIG. 3 is a circuit diagram illustrating the first physical circuit 132 of FIG. 2, according to an embodiment of the present disclosure.

Referring to FIG. 3, the first physical circuit 132 may include first to fifth transmitters 132_1 to 132_5, first and second synchronizers 132_6 and 132_7, data transfer circuit 132_8, and first and second receivers 132_9 and 132_10.

The first physical interface circuit 132 may receive an internal clock signal ICLK, an internal chip selection signal ICS, an internal command/address signal IC/A #, and write data WDATA from the first module controller 122, and transmit read data RDATA to the memory device 200. The internal clock signal ICLK may be provided in common to the first and second physical interface circuits 132 and 134 or may be provided separately to the first and second physical interface circuits 132 and 134. The read data RDATA and the write data WDATA may be composed of parallel data with a predetermined bit (e.g., 640 bits). For reference, the internal command/address signal IC/A #may be composed of a plurality of bits, and a reference symbol “#” indicating a plurality of bits is assigned.

The first transmitter 132_1 may receive the internal clock signal ICLK to output differential clock signals CLK_t and CLK_c. According to an embodiment, in order to minimize a skew, a delay line for variably delaying the internal clock signal ICLK for a predetermined time according to a result of a training operation may be disposed in front of the first transmitter 132_1. The differential clock signals CLK_t and CLK_c may be transmitted to the memory packages 201 to 208 through separate clock lines (not shown).

The first synchronizer 132_6 may receive the internal chip selection signal ICS in synchronization with an edge (e.g., a rising edge) of the internal clock signal ICLK. The second transmitter 132_2 may receive an output signal of the first synchronizer 132_6 to output a chip selection signal CS. The first synchronizer 132_6 may be implemented with a D-flip-flop. According to an embodiment, to minimize a skew, a delay line for variably delaying the internal clock signal ICLK for a predetermined time according to a result of a training operation may be disposed in front of the first synchronizer 132_6.

The second synchronizer 132_7 may receive the internal command/address signal IC/A #in synchronization with an edge (e.g., a rising edge) of the internal clock signal ICLK. The third transmitter 132_3 may receive an output signal of the second synchronizer 132_7 to output a command/address signal C/A #. The second synchronizer 132_7 may be implemented with a D-flip-flop. According to an embodiment, to minimize a skew, a delay line for variably delaying the internal clock signal ICLK for a predetermined time according to a result of a training operation may be disposed in front of the second synchronizer 132_7. Although FIG. 3 illustrates a case where the second synchronizer 132_7 and the third transmitter 132_3 are disposed one by one, they may be disposed by the number corresponding to the number of bits of the internal command/address signal IC/A #.

The chip selection signal CS and the command/address signal C/A #may be transmitted to the memory packages 201 to 208 through the control signal lines CTRL. Depending on an embodiment, the differential clock signals CLK_t and CLK_c may also be transmitted to the memory packages 201 to 208 through the control signal lines CTRL.

The data transfer circuit 132_8 may serialize the write data WDATA to generate a write strobe signal WDQS based on the serialized data. For example, the data transfer circuit 132_8 may serialize the 640-bit write data WDATA at 16:1, to generate the write strobe signal WDQS based on the serialized data. The fourth transmitter 132_4 may receive the serialized data from the data transfer circuit 132_8 to output data DATA, and the fifth transmitter 132_5 may transmit the write strobe signal WDQS generated by the data transfer circuit 132_8 as differential strobe signals DQS_t and DQS_c. The fifth transmitter 132_5 may generate the differential strobe signals DQS_t and DQS_c corresponding to the write strobe signal WDQS.

The first receiver 132_9 may receive the data DATA provided from the memory packages 201 to 208 to output the data DATA to the data transfer circuit 132_8, and the second receiver 132_10 may receive the differential strobe signals DQS_t and DQS_c provided from the memory packages 201 to 208 to generate a read strobe signal RDQS and transmit the read strobe signal RDQS to the data transfer circuit 132_8. The second receiver 132_10 may compare voltage levels of the differential strobe signals DQS_t and DQS_c to generate the read strobe signal RDQS. The data transfer circuit 132_8 may generate the read data RDATA by deserializing the data DATA transferred from the first receiver 132_9 according to the read strobe signal RDQS. For example, the data transfer circuit 132_8 may generate the 640-bit read data RDATA by deserializing the data input in series by 16 bits through the 40 data lines DQ<0:39>, according to the read strobe signal RDQS.

The data transfer circuit 132_8 may include a serializer/deserializer (SERDES) and a strobe generator. According to an embodiment, the strobe generator may receive the internal clock signal ICLK to generate the write strobe signal WDQS. Although FIG. 3 illustrates a case where the fourth transmitter 132_4 and the first receiver 132_9 are disposed one by one, they may be disposed by the number corresponding to the number (e.g., 40) of data lines DQ<0:39>.

The data DATA may be transmitted/received to/from the memory packages 201 to 208 through the data lines DQ<0:39>, and the differential strobe signals DQS_t and DQS_c may be transmitted/received to/from the memory packages 201 to 208 through the strobe line DQS.

As described above, the physical interface circuits 132 and 134 may be in one-to-one correspondence with the memory modules 200A and 200B and the module controllers 122 and 124. Each physical interface circuit may transmit/receive the write data WDATA or the read data RDATA in parallel to/from a corresponding module controller, and transmit/receive data converted according to a burst length to/from a corresponding memory module. In this case, the write data WDATA, the read data RDATA, and the data DATA may include user data UD and an error correction code ECC, respectively.

During a write operation, each module controller may generate an error correction code based on data corresponding to a request from the host device 20, and provide the write data WDATA including both the data and the error correction code to the physical interface circuit. The physical interface circuit may serialize the write data WDATA according to the burst length to output the data DATA having 64-byte user data UD and a 16-byte error correction code ECC to the memory packages 201 to 210. Accordingly, the memory packages 201 to 208 may store the 64-byte user data UD, and the memory packages 209 and 210 may store the 16-byte error correction code ECC. During a read operation, each physical interface circuit may receive the 64 byte user data UD and the 16-byte error correction code ECC, and deserialize the received user data UD and the received error correction code ECC into the read data RDATA, to output the read data RDATA to a corresponding module controller. The module controller may correct an error of the user data using the error correction code, and provide the error-corrected data to the host device 20.

In the memory system 10A according to the above embodiment, each memory module may transfer only dedicated user data and a dedicated error correction code through a corresponding physical interface circuit. That is, each memory module may store only a fixed number of error correction codes (or bits). In the following embodiment, a method of changing an error correction capability by selectively transmitting/receiving an error correction code for different memory modules to/from a specific memory module will be described.

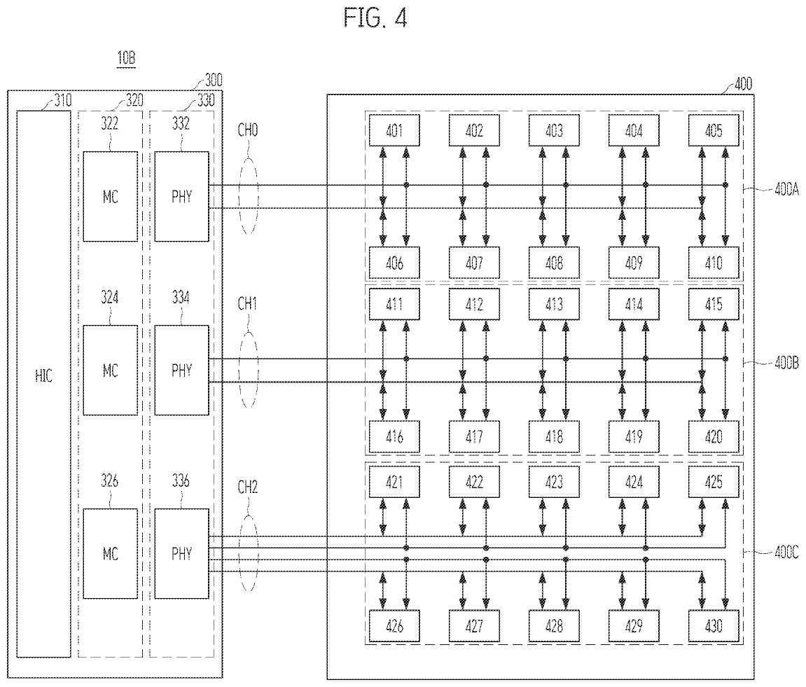

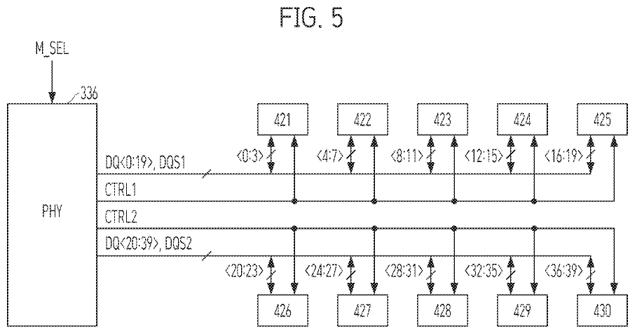

FIG. 4 is a block diagram illustrating a memory system 10B according to a second embodiment of the present disclosure. FIG. 5 is a diagram for describing a connection between a third physical interface circuit 336 and a third memory module 400C of FIG. 4, according to an embodiment of the present disclosure.

Referring to FIG. 4, the memory system 10B may include a memory controller 300 and a memory device 400.

The memory device 400 may include a plurality of memory modules that independently communicate with the memory controller 300 through channels CH0 to CH2 that are separated from each other. For example, the memory device 400 may include first to third memory modules 400A to 400C which communicate with the memory controller 300 through first to third channels CH0 to CH2, respectively. Each of the first to third memory modules 400A to 400C may include 10 memory packages. Specifically, the first module 400A may include memory packages 401 to 410, the second module 400B may include memory packages 411 to 420, and the third module 400A may include memory packages 421 to 430. Depending on an arrangement, the memory packages of each of the first to third memory modules 400A to 400C may be divided into lower memory packages and upper memory packages. For example, 5 memory packages among the 10 memory packages may be defined as lower memory packages, and the remaining 5 memory packages among the memory packages may be defined as upper memory packages, based on a horizontal or vertical direction.

The memory controller 300 may include a host interface circuit (HIC) 310, a module control logic 320, and a memory interface logic 330.

The host interface circuit 310 may communicate with a host device (20 in FIG. 1) through a host interface.

The module control logic 320 may be coupled to the memory device 400 through the memory interface logic 330 and control the overall operation of the memory device 400. The module control logic 320 may include first to third module controllers (MCs) 322 to 326 for controlling the first to third memory modules 400A to 400C, respectively.

The memory interface logic 330 may communicate with the memory device 400 through a memory interface. The memory interface logic 330 may include first to third physical interface circuits (PHYs) 332 to 336 which interface the first to third memory modules 400A to 400C to the first to third module controllers 322 to 326, respectively. The first to third physical interface circuits 332 to 336 may transmit control signals and transmit/receive data and a strobe signal to/from the first to third memory modules 400A to 400C, respectively, through an independent channel.

The first and second physical interface circuits 332 and 334 of FIG. 4 may have substantially the same configuration as the first and second physical interface circuits 132 and 134 of FIG. 2. That is, the first and second physical interface circuits 332 and 334 may transmit the control signals including a chip selection signal and a command/address signal to a corresponding memory module through control signal lines (CTRL of FIG. 2), and transmit/receive the data and the strobe signal to/from the corresponding memory module through data lines (DQ<0:39> of FIG. 2) and a strobe line (DQS of FIG. 2), respectively. User data and an error correction code may be stored in or read from memory packages through the data lines DQ<0:39>. Accordingly, the first physical interface circuit 332 may transfer only data and an error correction code for the first memory module 400A, and the second physical interface circuit 334 may transfer only user data and an error correction code for the second memory module 400B.

On the other hand, unlike the first and second physical interface circuits 332 and 334, the third physical interface circuit 336 may be coupled to lower and upper memory packages of the third memory module 400C through separate data lines, a strobe line, and control signal lines, respectively.

Referring to FIG. 5, the third physical interface circuit 336 may be coupled to lower memory packages 421 to 425 of the third memory module 400C through lower data lines DQ<0:19>, a lower strobe line DQS1 and first control signal lines CTRL1. In addition, the third physical interface circuit 336 may be coupled to upper memory packages 426 to 420 of the third memory module 400C through upper data lines DQ<20:39>, an upper strobe line DQS2 and second control signal lines CTRL2.

The third physical interface circuit 336 may transfer user data and an error correction code for the third memory module 400C, or transfer the error correction code for each of the first and second memory modules 400A and 400B different from the third memory module 400C according to a setting signal M_SEL in FIG. 5. The setting signal M_SEL may be generated based on a request from the host device 20. For example, when the setting signal M_SEL is set to a logic low level, the third physical interface circuit 336 may operate in a normal mode in which only the user data and error correction code for the third memory module 400C are transmitted/received to/from the third memory module 400C through the lower data lines DQ<0:19> and the upper data lines DQ<20:39>. On the other hand, when the set signal M_SEL is set to a logic high level, the third physical interface circuit 336 may operate in an extended mode in which the error correction code for the first memory module 400A is transmitted/received to/from the third memory module 400C through the lower data lines DQ<0:19>, and the error correction code for the second memory module 400B is transmitted/received to/from the third memory module 400C through the upper data lines DQ<20:39>.

In FIGS. 4 and 5, a case where the lower memory packages 421 to 425 and the upper memory packages 426 to 420 are classified according to the arrangement has been described as an example, but the embodiments of the present disclosure are not limited thereto. According to an embodiment, the memory packages in the third memory module 400C may be classified according to a shape, a stacking method, a memory type, and the like in addition to the arrangement. Further, in FIGS. 4 and 5, a case where 5 memory packages in the third memory module 400C are allocated to the lower memory packages 421 to 425 and the remaining 5 memory packages are allocated to the upper memory packages 426 to 420 has been described as an example, but the embodiments of the present disclosure are not limited thereto. According to an embodiment, each memory module may include 2n memory packages, where n is a positive integer, and each module controller may control m memory packages, where m is a positive integer, among 2n memory packages to store the error correction code for the first memory module 400A, and control the remaining (i.e., 2n−m) memory packages to store the error correction code for the second memory module 400B. For example, m may be set to n.

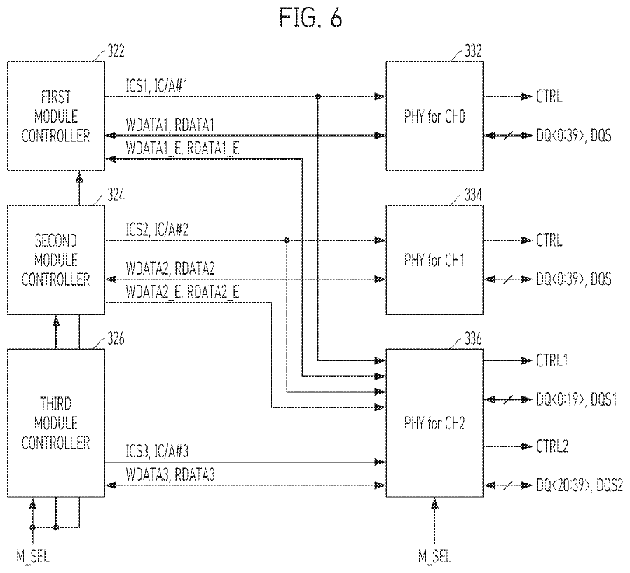

FIG. 6 is a diagram for describing input/output signals between the module control logic 320 and the memory interface logic 330 of FIG. 4, according to an embodiment of the present disclosure.

Referring to FIG. 6, the first module controller 322 may generate a first internal chip selection signal ICS1 and a first internal command/address signal IC/A #1 in response to a request from the host device 20.

During a write operation, the first module controller 322 may generate an error correction code based on data corresponding to the request from the host device 20, to output first write data WDATA1 including both the data and the error correction code to the first physical interface circuit 332. The first module controller 322 may selectively adjust a size (i.e., a bit width or a bandwidth) of the error correction code according to the setting signal M_SEL. The first module controller 322 may extend the size of the error correction code by 1/2 of the bits of the first write data WDATA1 according to the setting signal M_SEL. For example, when the setting signal M_SEL is set to a logic low level, the first module controller 322 may generate a 128-bit error correction code using 512-bit data. The first module controller 322 may provide 640-bit first write data WDATA1 including the 512-bit data and the 128-bit error correction code to the first physical interface circuit 332. On the other hand, when the setting signal M_SEL is set to a logic high level, the first module controller 322 may generate a 448-bit (i.e., 320+128) error correction code using 512-bit data. The first module controller 322 may provide the 640-bit first write data WDATA1 including the 512-bit data and the 128-bit error correction code while providing 320-bit first extended write data WDATA1_E including an extended 320-bit error correction code to the third physical interface circuit 336.

During a read operation, the first module controller 322 may receive first read data RDATA1 transmitted from the first physical interface circuit 332. The first module controller 322 may correct an error included in data using an error correction code included in the first read data RDATA1, to output the error-corrected data to the host device 20. The first module controller 322 may selectively receive first extended read data RDATA1_E transmitted from the third physical interface circuit 336 in response to the setting signal M_SEL and extend the size of the error correction code by 1/2 of the bits of the first write data WDATA1. For example, when the setting signal M_SEL is set to a logic low level, the first module controller 322 may correct an error of 512-bit data using a 128-bit error correction code, and when the setting signal M_SEL is set to a logic high level, the first module controller 322 may correct an error of the 512-bit data using a 448-bit (i.e., 320+128) error correction code to which the first extended read data RDATA1_E is added.

The first physical interface circuit 332 may receive the first internal chip selection signal ICS1 and the first internal command/address signal IC/A #1 from the first module controller 322, and transmit/receive the first write data WDATA1 and the first read data RDATA1 to/from the first module controller 322. The first physical interface circuit 332 may transmit control signals including a chip selection signal and a command/address signal to the first memory module 400A through the control signal lines CTRL, and transmit/receive data and a strobe signal to/from the first memory module 400A through the data lines DQ<0:39> and the strobe line DQS, respectively.

The second module controller 324 may have substantially the same configuration as the first module controller 322. The second module controller 324 may generate a second internal chip selection signal ICS2 and a second internal command/address signal IC/A #2 according to the request from the host device 20. The second module controller 324 may selectively adjust a size of an error correction code according to the setting signal M_SEL. During a write operation, the second module controller 324 may extend the size of the error correction code by 1/2 bits of second write data WDATA2 according to the setting signal M_SEL. The second module controller 324 may provide 512-bit data and a 128-bit error correction code to the second physical interface circuit 334 as the second write data WDATA2, and provide an extended 320-bit error correction code to the third physical interface circuit 336 as second extended write data WDATA2_E. During a read operation, the second module controller 324 may selectively receive second extended read data RDATA2_E transmitted from the third physical interface circuit 336 according to the setting signal M_SEL to extend the size of the error correction code by 1/2 of the bits (i.e., 320 bits) of the second write data WDATA2.

The second physical interface circuit 334 may have substantially the same configuration as the first physical interface circuit 332. The second physical interface circuit 334 may receive the second internal chip selection signal ICS2 and the second internal command/address signal IC/A #2 from the second module controller 324, and transmit/receive the second write data WDATA2 and the second read data RDATA2 to/from the second module controller 324. The second physical interface circuit 334 may transmit control signals including a chip selection signal and a command/address signal to the second memory module 400B through the control signal lines CTRL, and transmit/receive data and a strobe signal to/from the second memory module 400B through the data lines DQ<0:39> and the strobe line DQS, respectively.

The third module controller 326 may generate a third internal chip selection signal ICS3 and a third internal command/address signal IC/A #3 according to the request from the host device 20. During a write operation, the third module controller 326 may generate an error correction code based on data corresponding to the request from the host device 20, to output third write data WDATA3 including both the data and the error correction code to the third physical interface circuit 336. During a read operation, the third module controller 326 may correct an error included in data using an error correction code included in the third read data RDATA3 transmitted from the third physical interface circuit 336, to output the error-corrected data to the host device 20. The third module controller 326 may be deactivated when the setting signal M_SEL is set to a logic high level.

When the setting signal M_SEL is set to a logic low level, the third physical interface circuit 336 may receive the third internal chip selection signal ICS3 and the third internal command/address signal IC/A #3 from the third module controller 326, and transmit/receive the third write data WDATA3 and the third read data RDATA3 to/from the third module controller 326. When the setting signal M_SEL is set to a logic high level, the third physical interface circuit 336 may receive the first internal chip selection signal ICS1 and the first internal command/address signal IC/A #1 from the first module controller 322, and transmit/receive the first extended write data WDATA1_E and the first extended read data RDATA1_E to/from the first module controller 322. Further, when the set signal M_SEL is set to a logic high level, the third physical interface circuit 336 may receive the second internal chip selection signal ICS2 and the second internal command/address signal IC/A #2 from the second module controller 324, and transmit/receive the second extended write data WDATA2_E and the second extended read data RDATA2_E to/from the second module controller 324.

The first to third physical interface circuits 332 to 336 may receive the internal clock signal ICLK in common and provide it to each memory module as a clock signal. The first extended write data WDATA1_E and the first extended read data RDATA1_E may be defined as a first extended error correction code, and the second extended write data WDATA2_E and the second extended read data RDATA2_E may be defined as a second extended error correction code.

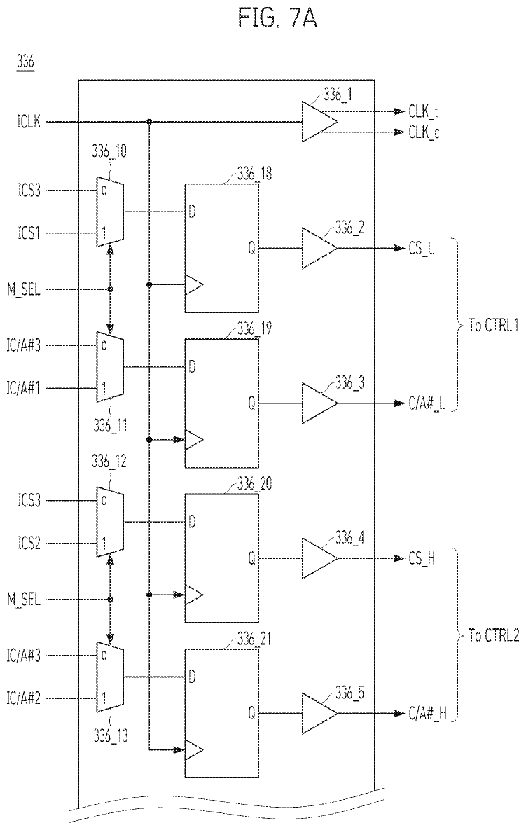

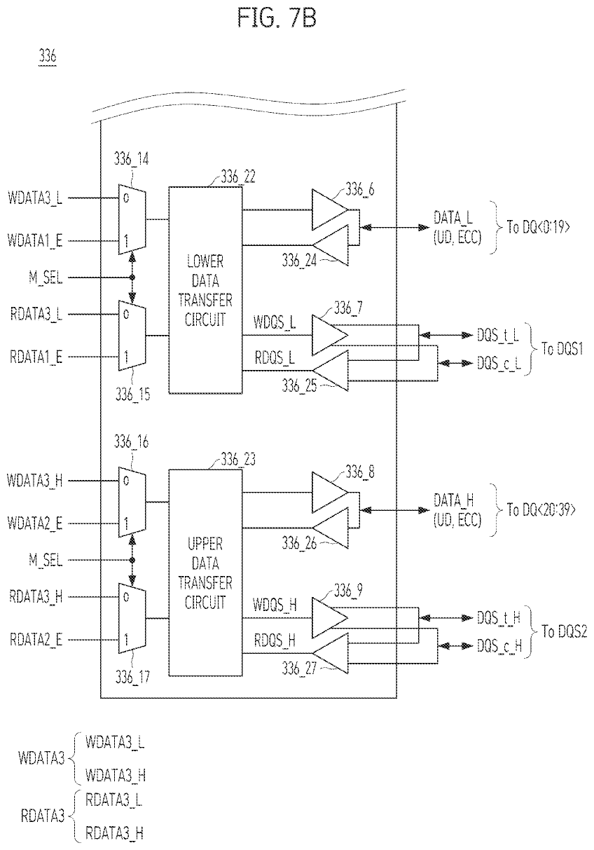

FIGS. 7A and 7B are circuit diagrams of the third physical interface circuit 336 of FIG. 6, according to an embodiment of the present disclosure.

Referring to FIGS. 7A and 7B, the third physical interface circuit 336 may include first to ninth transmitters 336_1 to 336_9, first to eighth selection circuits 336_10 to 336_17, first and fourth synchronizers 336_18 to 336_21, a lower data transfer circuit 336_22, an upper data transfer circuit 336_23, and first to fourth receivers 336_24 to 336_27.

The first transmitter 336_1 may receive the internal clock signal ICLK and transmit the received internal clock signal ICLK as differential clock signals CLK_t and CLK_c. According to an embodiment, in order to minimize a skew, a delay line for variably delaying the internal clock signal ICLK for a predetermined time according to a result of a training operation may be disposed in front of the first transmitter 336_1. The differential clock signals CLK_t and CLK_c may be transmitted to the third memory module 400C through separate clock lines (not shown).

The first selection circuit 336_10 may select one of the third internal chip selection signal ICS3 and the first internal chip selection signal ICS1 according to the setting signal M_SEL. For example, when the setting signal M_SEL is set to a logic high level, the first selection circuit 336_10 may select the first internal chip selection signal ICS1. The first synchronizer 336_18 may receive an output signal of the first selection circuit 336_10 in synchronization with an edge (e.g., a rising edge) of the internal clock signal ICLK. The first synchronizer 336_18 may receive the output signal of the first selection circuit 336_10 according to the internal clock signal ICLK. The second transmitter 336_2 may receive an output signal of the first synchronizer 336_18 and output its output signal as a lower chip selection signal CS_L. The first synchronizer 336_18 may be implemented with a D-flip-flop. According to an embodiment, a delay may be disposed in front of the first synchronizer 336_18.

The second selection circuit 336_11 may select one of the third internal command/address signal IC/A #3 and the first internal command/address signal IC/A #1 according to the set signal M_SEL. For example, when the set signal M_SEL is set to a logic high level, the second selection circuit 336_11 may select the first internal command/address signal IC/A #1. The second synchronizer 336_19 may receive an output signal of the second selection circuit 336_11 in synchronization with the internal clock signal ICLK. The third transmitter 336_3 may receive an output signal of the second synchronizer 336_19 and output its output signal as a lower command/address signal C/A #_L. According to an embodiment, a delay line may be disposed in front of the second synchronizer 336_19. Although FIG. 7A illustrates a case where the second selection circuit 336_11, the second synchronizer 336_19, and the third transmitter 336_3 are disposed one by one, they may be disposed by the number corresponding to the number of bits of the lower command/address signal C/A #_L.

The lower chip selection signal CS_L and the lower command/address signal C/A #_L may be transmitted to the lower memory packages 421 to 425 through the first control signal lines CTRL1.

The third selection circuit 336_12 may select one of the third internal chip selection signal ICS3 and the second internal chip selection signal ICS2 according to the set signal M_SEL. For example, when the set signal M_SEL is set to a logic high level, the third selection circuit 336_12 may select the second internal chip selection signal ICS2. The third synchronizer 336_20 may receive an output signal of the third selection circuit 336_12 in synchronization with the internal clock signal ICLK. The fourth transmitter 336_4 may receive an output signal of the third synchronizer 336_20 and output its output signal as an upper chip selection signal CS_H. According to an embodiment, a delay line may be disposed in front of the third synchronizer 336_20.

The fourth selection circuit 336_13 may select one of the third internal command/address signal IC/A #3 and the second internal command/address signal IC/A #2 according to the set signal M_SEL. For example, when the set signal M_SEL is set to a logic high level, the fourth selection circuit 336_13 may select the second internal command/address signal IC/A #2. The fourth synchronizer 336_21 may receive an output signal of the fourth selection circuit 336_13 in synchronization with the internal clock signal ICLK. The fifth transmitter 336_5 may receive an output signal of the fourth synchronizer 336_21, and output its output signal as an upper command/address signal C/A #_H. According to an embodiment, a delay line may be disposed at the front end of the fourth synchronizer 336_21. Although FIG. 7A illustrates a case where the fourth selection circuit 336_13, the fourth synchronizer 336_21, and the fifth transmitter 336_5 are disposed one by one, they may be disposed by the number corresponding to the number of bits of the upper command/address signal C/A #_H.

The upper chip selection signal CS_H and the upper command/address signal C/A #_H may be transmitted to the upper memory packages 426 to 430 through the second control signal lines CTRL2.

Referring to FIG. 7B, the fifth selection circuit 336_14 may select one of lower data of the third write data WDATA3 (hereinafter, referred to as third lower write data WDATA3_L) and the first extended write data WDATA1_E according to the set signal M_SEL. For example, when the set signal M_SEL is set to a logic high level, the fifth selection circuit 336_14 may select the first extended write data WDATA1_E. The lower data transfer circuit 336_22 may serialize an output signal of the fifth selection circuit 336_14 to generate a lower write strobe signal WDQS_L based on the serialized data. The sixth transmitter 336_6 may receive the serialized data from the lower data transfer circuit 336_22 to output lower data DATA_L, and the seventh transmitter 336_7 may transfer the lower write strobe signal WDQS_L generated by the lower data transfer circuit 336_22 as differential strobe signals DQS_t_L and DQS_c_L. The seventh transmitter 336_7 may generate the differential strobe signals DQS_t_L and DQS_c_L corresponding to the lower write strobe signal WDQS_L.

The first receiver 336_24 may receive the lower data DATA_L provided from the lower memory packages 421 to 425 to output the lower data DATA_L to the lower data transfer circuit 336_22, and the second receiver 336_25 may receive the differential strobe signals DQS_t_L and DQS_c_L provided from the lower memory packages 421 to 425 to generate a lower read strobe signal RDQS_L, and transmit the lower read strobe signal RDQS_L to the lower data transfer circuit 336_22. The second receiver 336_25 may compare voltage levels of the differential strobe signals DQS_t_L and DQS_c_L to generate the lower read strobe signal RDQS_L. The lower data transfer circuit 336_22 may deserialize the lower data DATA_L transferred from the first receiver 336_24 according to the lower read strobe signal RDQS_L. The sixth selection circuit 336_15 may select, according to the setting signal M_SEL, the deserialized lower data to be outputted as one of lower data (hereinafter, referred to as third lower read data RDATA3_L) of the third read data RDATA3 and the first extended read data RDATA1_E. For example, the sixth selection circuit 336_15 may output the deserialized lower data as the first extended read data RDATA1_E when the set signal M_SEL is set to a logic high level.

The lower data transfer circuit 336_22 may include a serializer/deserializer (SERDES) and a strobe generator. According to an embodiment, the strobe generator may receive the internal clock signal ICLK to generate the lower write strobe signal WDQS_L. Although FIG. 7B illustrates a case where the fifth selection circuit 336_14, the sixth selection circuit 336_15, the sixth transmitter 336_6, and the first receiver 336_24 are disposed one by one, they may be disposed by the number corresponding to the number (e.g., 20) of the lower data lines DQ<0:19>.

The lower data DATA_L may be transmitted/received from/to the lower memory packages 421 to 425 through the lower data lines DQ<0:19>, and the differential strobe signals DQS_t_L and DQS_c_L may be transmitted/received from/to the lower memory packages 421 to 425 through the lower strobe lines DQS1.

The seventh selection circuit 336_16 may select one of upper data (hereinafter, referred to as third upper write data WDATA3_H) of the third write data WDATA3 and the second extended write data WDATA2_E according to the set signal M_SEL. The seventh selection circuit 336_16 may select the second extended write data WDATA2_E when the set signal M_SEL is set to a logic high level. The upper data transfer circuit 336_23 may serialize an output signal of the seventh selection circuit 336_16 to generate an upper write strobe signal WDQS_H based on the serialized data. The eighth transmitter 336_8 may receive the serialized data from the upper data transfer circuit 336_23 to output upper data DATA_H, and the ninth transmitter 336_9 may transfer the upper write strobe signal WDQS_H generated by the upper data transfer circuit 336_23 as differential strobe signals DQS_t_H and DQS_c_H.

The third receiver 336_26 may receive the upper data DATA_H provided from the upper memory packages 426 to 430 to output the upper data DATA_H to the upper data transfer circuit 336_23, and the fourth receiver 336_27 may receive the differential strobe signals DQS_t_H and DQS_c_H provided from the upper memory packages 426 to 430 to generate an upper read strobe signal RDQS_H, and transmit the upper read strobe signal RDQS_H to the upper data transfer circuit 336_23. The upper data transfer circuit 336_23 may deserialize the upper data DATA_H transferred from the third receiver 336_26 according to the upper read strobe signal RDQS_H. The eighth selection circuit 336_17 may select, according to the set signal M_SEL, the deserialized upper data to be outputted as one of upper data (hereinafter referred to as third upper read data RDATA3_H) of the third read data RDATA3 and the second extended read data RDATA2_E. For example, the eighth selection circuit 336_17 may output the deserialized upper data as the second extended read data RDATA2_E when the set signal M_SEL is set to a logic high level.

The upper data transfer circuit 336_23 may include a serializer/deserializer (SERDES) and a strobe generator. According to an embodiment, the strobe generator may receive the internal clock signal ICLK to generate the upper write strobe signal WDQS_H. Although FIG. 7B illustrates a case where the seventh selection circuit 336_16, the eighth selection circuit 336_17, the eighth transmitter 336_8, and the third receiver 336_26 are disposed one by one, they may be disposed by the number corresponding to the number (e.g., 20) of the upper data lines DQ<20:39>.

The upper data DATA_H may be transmitted/received from/to the upper memory packages 426 to 430 through the upper data lines DQ<20:39>, and the differential strobe signals DQS_t_H and DQS_c_H may be transmitted/received from/to the upper memory packages 426 to 430 through the upper strobe lines DQS2.

Hereinafter, a configuration of the memory system 10B according to the setting signal M_SEL will be described with reference to FIGS. 4 to 8B.

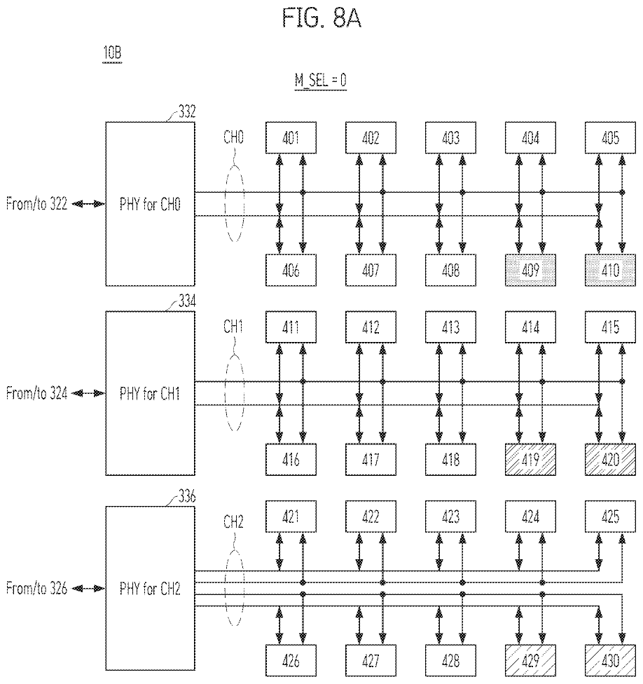

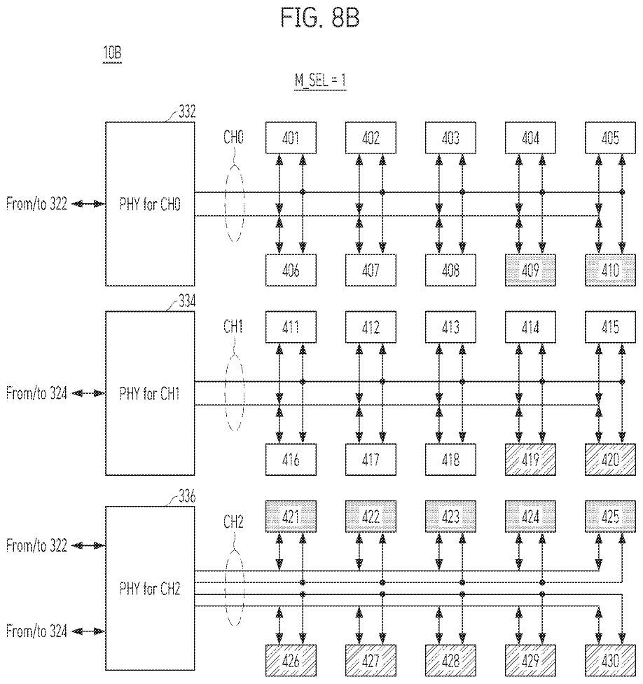

FIGS. 8A and 8B are diagrams for describing a configuration of the memory system 10B according to the setting signal M_SEL in accordance with embodiments of the present disclosure.

Referring to FIG. 8A, when the setting signal M_SEL is set to a logic low level, the third physical interface circuit 336 may receive the third internal chip selection signal ICS3 provided from the third module controller 326 to generate the lower chip selection signal CS_L and the upper chip selection signal CS_H, and receive the third internal command/address signal IC/A #3 provided from the third module controller 326 to generate the lower command/address signal C/A #_L and the upper command/address signal C/A #_H (see FIG. 7A). The third physical interface circuit 336 may receive the third lower write data WDATA3_L provided from the third module controller 326 to generate the lower data DATA_L, and receive the third upper write data WDATA3_H provided from the third module controller 326 to generate the upper data DATA_H (see FIG. 7B). In addition, the third physical interface circuit 336 may receive the lower read strobe signal RDQS_L together with the lower data DATA_L from the lower memory packages 421 to 425 to output the third lower read data RDATA3_L to the third module controller 326, receive the upper read strobe signal RDQS_H together with the upper data DATA_H from the upper memory packages 426 to 430 to output the third upper read data RDATA3_H to the third module controller 326 (see FIG. 7B).

The lower chip selection signal CS_L and the lower command/address signal C/A #_L may be transmitted to the lower memory packages 421 to 425 through the first control signal lines CTRL1, and the upper chip selection signal CS_H and the upper command/address signal C/A #_H may be transmitted to the upper memory packages 426 to 430 through the second control signal lines CTRL2. The lower data DATA_L may be transmitted/received to/from the lower memory packages 421 to 425 through the lower data lines DQ<0:19>, and the upper data DATA_H may be transmitted/received to/from the upper memory packages 426 to 430 through the upper data lines DQ<20:39>. For reference, the differential strobe signals DQS_t_L and DQS_c_L together with the lower data DATA_L may be transmitted/received to/from the lower memory packages 421 to 425 through the lower strobe line DQS1, and the differential strobe signals DQS_t_H and DQS_c_H together with the upper data DATA_H may be transmitted/received to/from the upper memory packages 426 to 430 through the upper strobe line DQS2.

Accordingly, as shown in FIG. 8A, when the setting signal M_SEL is a logic low level, the third physical interface circuit 336 may transmit/receive user data and an error correction code for the third memory module 400C to/from the third memory module 400C through the data lines DQ<0:39>. In this case, 8 memory packages 421 to 428 among the 10 memory packages 421 to 430 may be used to store the user data UD, and the remaining two memory packages 429 and 430 may be used to store the error correction code ECC. Meanwhile, FIG. 8A shows a case where the memory packages 429 and 430 are used to store the error correction code ECC, but the embodiments of the present disclosure are not limited thereto, and the error correction code ECC may be stored in some (e.g., 425 and 430) among the 10 memory packages 421 to 430.

Referring to FIG. 8B, when the setting signal M_SEL is set to a logic high level, the third physical interface circuit 336 may receive the first internal chip selection signal ICS1 provided from the first module controller 322 to generate the lower chip selection signal CS_L, and receive the second internal chip selection signal ICS2 provided from the second module controller 324 to generate the upper chip selection signal CS_H. The third physical interface circuit 336 may receive the first internal command/address signal IC/A #1 provided from the first module controller 322 to generate the lower command/address signal C/A #_L, and receive the second internal command/address signal IC/A #2 provided from the second module controller 324 to generate the upper command/address signal C/A #_H (see FIG. 7A). The third physical interface circuit 336 may receive the first extended write data WDATA1_E provided from the first module controller 322 to generate the lower data DATA_L, and receive the second extended write data WDATA2_E provided from the second module controller 324 to generate the upper data DATA_H (see FIG. 7B). Further, the third physical interface circuit 336 may receive the lower read strobe signal RDQS_L together with the lower data DATA_L from the lower memory packages 421 to 425 to output the first extended read data RDATA1_E to the first module controller 322, and receive the upper read strobe signal RDQS_H together with the upper data DATA_H from the upper memory packages 426 to 430 to output the second extended read data RDATA2_E to the second module controller 324 (see FIG. 7B).

Accordingly, as shown in FIG. 8B, when the set signal M_SEL is a logic high level, the third physical interface circuit 336 may transmit/receive the first extended error correction code (i.e., the first extended write data WDATA1_E and the first extended read data RDATA1_E) to/from the lower memory packages 421 to 425 through the lower data lines DQ<0:19>, and transmit/receive the second extended error correction code (i.e., the second extended write data WDATA2_E and the second extended read data RDATA2_E) to/from the upper memory packages 426 to 430 through the upper data lines DQ<20:39>. That is, the third physical interface circuit 336 may transfer the error correction code for each of the first and second memory modules 400A and 400B different from the third memory module 400C.

As described above, when the set signal M_SEL is set to a logic low level, the memory system 10B may operate in a normal mode to input/output 64-byte user data and a 16-byte error correction code for each of the first to third memory modules. On the other hand, when the set signal M_SEL is set to a logic high level, the memory system 10B may operate in an extended mode to input/output a 40-byte error correction code in addition to 64-byte user data and a 16-byte error correction code for each of the first and second memory modules. That is, the memory system 10B may use a 56-byte (i.e., 16+40) error correction code for each of the first and second memory modules, by adding a 40-byte extended error correction code and the 16-yte error correction code. In this case, each of the first and second extended error correction codes may have a size of 40 bytes corresponding to half of the 64-byte user data and the 16-byte error correction code. The memory system 10B may vary the error correction capability in consideration of a case in which an increase in memory capacity is required or a case in which the high-performance error correction capability is required. Accordingly, it is possible to flexibly cope with the system environment by increasing the error correction capability only in the extended mode where the high-performance error correction capability is required.

In the above embodiment, a case where memory packages storing user data and an error correction code are arranged in each memory module has been described as an example, but the embodiments of the present disclosure are not limited thereto. In a normal mode, only user data may be stored in each memory module, and in an extended mode, an error correction code for other memory modules may be stored in one memory module.

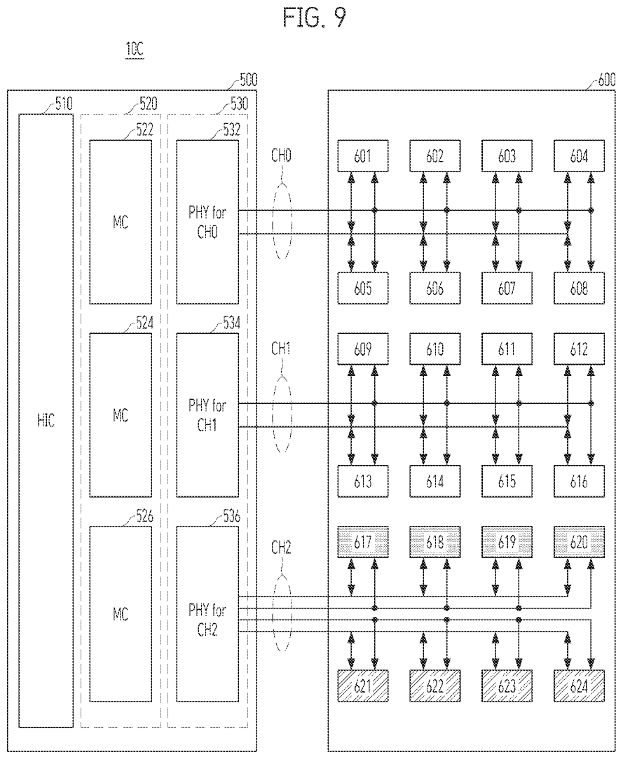

FIG. 9 is a diagram for describing a modified example of a memory system 10C according to an embodiment of the present disclosure.

Referring to FIG. 9, the memory system 10C may include a memory controller 500 and a memory device 600.

The memory device 600 may include a plurality of memory modules that independently communicate with the memory controller 500 through channels CH0 to CH2 that are separated from each other. For example, as shown in FIG. 9, the memory device 600 may include a first memory module 601 to 608, a second memory module 609 to 616, and a third memory module 617 to 624, which respectively communicate with the memory controller 500 through first to third channels CH0 to CH2.

The memory controller 500 may include a host interface circuit (HIC) 510, a module control logic 520, and a memory interface logic 530.

The host interface circuit 510 may communicate with the host device (20 in FIG. 1) through a host interface.

The module control logic 520 may be coupled to the memory device 600 through the memory interface logic 530 and control the overall operation of the memory device 600. The module control logic 520 may include first to third module controllers (MCs) 522 to 526 for controlling the first to third memory modules 601 to 608, 609 to 616, and 617 to 624, respectively.

The memory interface logic 530 may communicate with the memory device 600 through a memory interface. The memory interface logic 530 may include first to third physical interface circuits (PHYs) 532 to 536 which interface first to third memory modules 601 to 608, 609 to 616, and 617 to 624 and first to third module controllers 522 to 526, respectively, through an independent channel. Unlike the memory device 300 of FIG. 4, each of the first to third memory modules 601 to 608, 609 to 616, and 617 to 624 of FIG. 9 may include 8 memory packages. The first to third physical interface circuits 532 to 536 may transmit/receive user data to/from the 8 memory packages through 32 data lines, respectively. When a burst length is set to 16, the 8 memory packages may input and output 64 bytes of data at a time.

In FIG. 9, the first physical interface circuit 532 may transfer only 64-byte user data for the first memory module 601 to 608, and the second physical interface circuit 534 may transfer only 64-byte user data for the second memory module 609 to 616. On the other hand, the third physical interface circuit 536 may transfer 64-byte user data for the third memory modules 617 to 624, or transfer first and second extended error correction codes for the first and second memory modules 601 to 608 and 609 to 616, according to a setting signal M_SEL. In a normal mode in which the setting signal M_SEL is a logic low level, the third physical interface circuit 536 may transfer the user data for the third memory modules 617 to 624 through data lines. In an extended mode in which the set signal M_SEL is a logic low level, the third physical interface circuit 536 may transmit/receive the first extended error correction code to/from the lower memory packages 617 to 620 through lower data lines, and transmit/receive the second extended error correction code to/from the upper memory packages 621 to 624 through upper data lines.

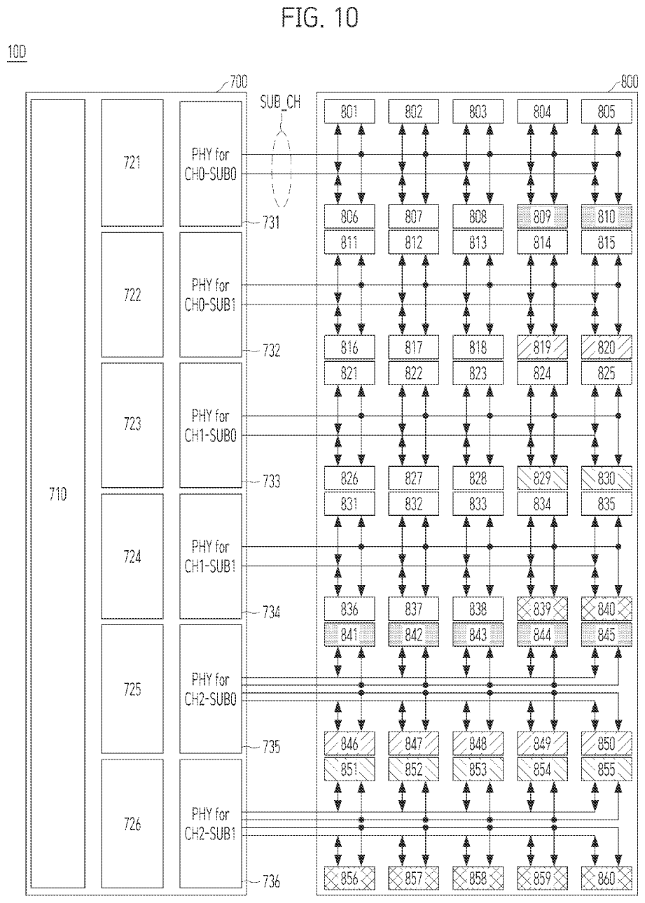

FIG. 10 is a diagram for describing another modified memory system 10D according to an embodiment of the present disclosure.

Referring to FIG. 10, the memory system 10D may include a memory controller 700 and a memory device 800.

The memory device 800 may include a plurality of sub-memory modules that independently communicate with the memory controller 700 through sub-channels CH_SUB that are separated from each other. For example, as shown in FIG. 10, the memory device 800 may include first to sixth sub-memory modules 801 to 810, 811 to 820, 821 to 830, 831 to 840, 841 to 850, and 851 to 860, which communicate with the memory controller 700 through first to sixth sub-channels CH_SUB, respectively.

The memory controller 700 may include a host interface circuit 710, first to sixth sub-module controllers 721 to 726, and first to sixth physical interface circuits 731 to 736.

The first to sixth physical interface circuits 731 to 736 may interface the first to sixth sub-module controllers 721 to 726 with the first to sixth sub-memory modules 801 to 820, 811 to 830, 831 to 840, 841 to 850, and 851 to 860, respectively. Each sub-memory module may correspond to one rank, and in FIG. 10, two ranks (i.e., two sub-memory modules) constitute one memory module. That is, the two sub-channels CH_SUB may form one channel CH.

The first to fourth sub-module controllers 721 to 724 of FIG. may have substantially the same configuration as the first and second module controllers 322 and 324 of FIG. 4, and the first to fourth physical interface circuits 731 to 734 may have substantially the same configuration as the first and second physical interface circuits 332 and 334 of FIG. 4. Further, the fifth and sixth sub-module controllers 725 and 726 of FIG. 10 may have substantially the same configuration as the third module controller 326 of FIG. 4, and the fifth and sixth physical interface circuits 735 and 736 may have substantially the same configuration as the third physical interface circuit 336 of FIG. 4.

When a setting signal M_SEL is set to a logic low level, the memory system 10D may operate in a normal mode to input/output 64-byte user data and a 16-byte error correction code to/from each of the first to sixth sub-memory modules 801 to 810, 811 to 820, 821 to 830, 831 to 830, 841 to 850, and 851 to 860. On the other hand, when the setting signal M_SEL is set to a logic high level, the memory system 10D may operate in an extended mode to input/output 64-byte user data and a 16-byte error correction code to/from each of the first to fourth sub-memory modules 801 to 820, 821 to 830, and 831 to 840, input/output a 40-byte error correction code for the first sub-memory module 801 to 810 and a 40-byte error correction code for the second sub-memory module 811 to 820, to/from the fifth sub-memory modules 841 to 850, and input/output a 40-byte error correction code for the third sub-memory module 821 to 830 and a 40-byte error correction code for the fourth sub-memory module 841 to 850, to/from the sixth sub-memory modules 851 to 860.

Various embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the disclosure and the following claims.

For example, for the logic gates and transistors provided as examples in the above-described embodiments, different positions and types may be implemented depending on the polarity of the input signal.

What is claimed is:

1. A memory system comprising:
a plurality of memory modules;
a plurality of module controllers configured to respectively control the plurality of memory modules; and
a plurality of interface circuits configured to interface the plurality of memory modules with the plurality of module controllers, wherein, according to a setting signal, at least one target interface circuit is configured to interface a target module controller among the plurality of module controllers with a target memory module among the plurality of memory modules, or interface other module controllers different from the target module controller with the target memory module.

2. The memory system of claim 1,
wherein the target interface circuit is configured to transfer, between the target module controller and the target memory module, user data and an error correction code for the target memory module, in response to the setting signal having a first logic level, and
wherein the target interface circuit is configured to transfer, between the other module controllers and the target memory module, extended error correction codes for other memory modules different from the target memory module, in response to the setting signal having a second logic level.

3. The memory system of claim 2, wherein each of the other module controllers is configured to generate user data and an error correction code for a corresponding memory module, generate the extended error correction code by increasing a size of the error correction code according to the setting signal, and output the extended error correction code to the target interface circuit.

4. The memory system of claim 2,
wherein each of the plurality of memory modules includes 2n memory packages, wherein n is a positive integer, and
wherein, according to the setting signal, the target interface circuit is configured to transfer an extended error correction code for a first memory module among the other memory modules, to n memory packages of the target memory module, and transfer an extended error correction code for a second memory module among the other memory modules, to remaining n memory packages of the target memory module.

5. The memory system of claim 1,
wherein each of the plurality of memory modules includes 2n memory packages, wherein n is a positive integer, and
wherein the target interface circuit is coupled to n memory packages of the target memory module through first data lines transmitting upper data and a first strobe line transmitting an upper strobe signal, and coupled to remaining n memory packages of the target memory module through second data lines transmitting lower data and a second strobe line transmitting a lower strobe signal.

6. The memory system of claim 5, wherein each interface circuit except for the target interface circuit, among the plurality of interface circuits, is coupled to 2n memory packages of a corresponding memory module through data lines transmitting upper and lower data and a strobe line transmitting a strobe signal.

7. The memory system of claim 1,
wherein each of the plurality of memory modules includes m memory packages, and
wherein k memory packages are disposed to store user data, and remaining (m−k) memory packages are disposed to store an error correction code, wherein m is a positive integer of 2 or more and k is a positive integer less than m.

8. The memory system of claim 1, wherein each of the plurality of memory modules includes m memory packages, wherein m is a positive integer of 2 or more, and the m memory packages are disposed to store user data.

9. The memory system of claim 1, wherein the target interface circuit includes:
a first receiver configured to receive lower read data from the target memory module;
a first selection circuit configured to select data from a first module controller or the target module controller, according to the setting signal;
a first serializer/deserializer configured to serialize an output signal of the first selection circuit and deserialize the lower read data;
a first transmitter configured to transmit the serialized data from the first serializer/deserializer to the target memory module as lower write data;
a second selection circuit configured to select the deserialized data from the first serializer/deserializer to be outputted to the first module controller or the target module controller, according to the setting signal;
a second receiver configured to receive upper read data from the target memory module;
a third selection circuit configured to select data from a second module controller or the target module controller, according to the setting signal;
a second serializer/deserializer configured to serialize an output signal of the third selection circuit and deserialize the upper read data;
a second transmitter configured to transmit the serialized data from the second serializer/deserializer to the target memory module as upper write data; and
a fourth selection circuit configured to select the deserialized data from the second serializer/deserializer to be outputted to the second module controller or the target module controller.

10. The memory system of claim 9, wherein the target interface circuit further includes:
a fifth selection circuit configured to select control signals from the first module controller or the target module controller, according to the above setting signal;
a third transmitter configured to transmit, as lower control signals, an output signal of the fifth selection circuit to the target memory module;
a sixth selection circuit configured to select control signals from the second module controller or the target module controller, according to the above setting signal; and
a fourth transmitter configured to transmit, as upper control signals, an output signal of the sixth selection circuit to the target memory module.

11. The memory system of claim 1, further comprising:
a host interface circuit configured to communicate with a host using a compute express link (CXL) interface.

12. The memory system of claim 1, wherein the memory system has a form factor of either Add-in-Card (AIC) or Enterprise and Data Center SSD Form Factor (EDSFF).

13. A memory system comprising:
first to third memory modules;
first to third module controllers configured to generate user data and an error correction code for the first to third memory modules, respectively; and
first to third interface circuits configured to transmit and receive the user data and the error correction code to and from the first to third memory modules, respectively, through independent channels,
wherein the first and second module controllers are configured to respectively increase a size of the error correction code according to a setting signal to generate first and second extended error correction codes, and
wherein the third interface circuit is configured to transmit/receive the first and second extended error correction codes to/from the third memory module according to the setting signal.

14. The memory system of claim 13, wherein each of the first and second extended error correction codes includes a size corresponding to half of a number of bits of the user data and the error correction code.

15. The memory system of claim 13,
wherein the first to third interface circuits are configured to respectively transmit and receive x-bit user data and a y-bit error correction code to and from the first to third memory modules, in response to the setting signal having a first logic level, and
wherein the first and second interface circuits are configured to respectively transmit and receive x-bit user data and a y-bit error correction code to and from the first and second memory modules, and the third interface circuit is configured to transmit and receive the first and second extended error correction codes each having a (x+y)/2-bit size, to and from the third memory module, in response to the setting signal having a second logic level.

16. The memory system of claim 13,
wherein each of the first to third memory modules includes 2n memory packages, wherein n is a positive integer, and
wherein, according to the setting signal, the third interface circuit is configured to transmit and receive the first extended error correction code to and from n memory packages of the third memory module, and transmit and receive the second extended error correction code to and from remaining n memory packages of the third memory module.

17. The memory system of claim 13, wherein the setting signal is generated based on a request from a host.

18. A memory controller comprising:
first to third module controllers configured to generate user data and an error correction code for first to third memory modules, respectively; and
first to third interface circuits configured to transmit and receive the user data and the error correction code to and from the first to third memory modules, respectively, through independent channels,
wherein the first and second module controllers are configured to respectively increase a size of the error correction code according to a setting signal to generate first and second extended error correction codes, and
wherein the third interface circuit is configured to transmit and receive the first and second extended error correction codes to and from the third memory module according to the setting signal.

19. The memory controller of claim 18, wherein each of the first and second extended error correction codes includes a size corresponding to half of a number of bits of the user data and the error correction code.

20. The memory controller of claim 18,
wherein the first to third interface circuits are configured to respectively transmit and receive x-bit user data and a y-bit error correction to and from the first to third memory modules, in response to the setting signal having a first logic level, and
wherein the first and second interface circuits are configured to respectively transmit and receive x-bit user data and a y-bit error correction to and from the first and second memory modules, and the third interface circuit is configured to transmit and receive the first and second extended error correction codes each having a (x+y)/2-bit size, to/from the third memory module, in response to the setting signal having a second logic level.
